(19) United States
(12) Patent Application Publication
(10) Pub. No.: US 2007/0148820 A1
(43) Pub. Date: Jun. 28, 2007

(54) Microelectronic devices and methods for manufacturing microelectronic devices

(75) Inventor: Blaine J. Thurgood, Nampa, ID (US)

Correspondence Address: PERKINS COIE LLP;PATENT-SEA, PO BOX 1247, SEATTLE, WA, 98111-1247, US

(73) Assignee: Micron Technology, Inc., Boise, ID (US)

(21) Appl. No.: 11/317,438

(22) Filed: Dec. 22, 2005

(51) Int. Cl. H01L 21/00

(52) U.S. Cl. 438/109; 438/127

(57) ABSTRACT

Microelectronic devices and methods for manufacturing microelectronic devices are disclosed herein. An embodiment of one such method includes attaching a first die to a support member, coupling a second die to the first die with the first die positioned between the second die and the support member, and placing the first die, the second die, and the support member in a cavity of a mold with a plurality of stand-offs positioned between an adjacent internal wall of the mold and the support member such that at least a portion of the support member is spaced apart from the internal wall of the mold. The method further includes injecting a mold compound into the mold cavity to encapsulate the first die, the second die, and at least a portion of the support member.

### TECHNICAL FIELD

The present invention is related to microelectronic devices and methods for manufacturing microelectronic devices.

### BACKGROUND

Microelectronic devices generally have a die (i.e., a chip) that includes integrated circuitry with a high density of very small components. In a typical process, a large number of dies are manufactured on a single wafer using many different processes that may be repeated at various stages (e.g., implanting, doping, photolithography, chemical vapor deposition, plasma vapor deposition, plating, planarizing, and etching). The dies typically include an array of very small bond-pads electrically coupled to the integrated circuitry. The bond-pads are external electrical contacts through which the supply voltage, signals, etc., are transmitted to and from the integrated circuitry. The dies are then separated from one another (i.e., singulated) by dicing the wafer and backgrinding the individual dies. After the dies have been singulated, they are typically “packaged” to couple the bond-pads to a larger array of electrical terminals that can be more easily coupled to the various power supply lines, signal lines, and ground lines. Conventional processes for packaging dies include electrically coupling the bond-pads on the dies to an array of leads, ball-pads, or other types of electrical terminals, and then encapsulating the dies to protect them from environmental factors (e.g., moisture, particulates, static electricity, and physical impact).

Leaded packages, for example, include a die bonded to a lead frame with either the die seated on a die paddle or attached directly to the leads in a leads-over-chip arrangement. The bond-pads on the die are then wire-bonded to corresponding leads. The lead frame and die may then be encapsulated with a mold compound to form a packaged microelectronic device. In several applications, a heat sink can be attached to the lead frame before the die and lead frame are encapsulated.

Electronic products require packaged microelectronic devices to have an extremely high density of components in a very limited space. For example, the space available for memory devices, processors, displays, and other microelectronic components is quite limited in cell phones, PDAs, portable computers, and many other products. As such, there is a strong drive to reduce the surface area or “footprint” of a microelectronic device on a printed circuit board. Reducing the size of microelectronic devices is difficult because high performance dies generally have more bond-pads, which increases the lead count and produces a larger footprint.

One technique used to increase the density of dies within a given footprint is to stack one die on top of another. Stacking just one die on top of a second die can effectively double the circuitry within a given footprint. For example, FIG. 1 schematically illustrates a microelectronic component assembly 1 including a lead frame 20 and first and second dies 10a-b attached to the lead frame 20. The lead frame 20 includes a die paddle 22 carrying the dies 10a-b and a plurality of leads 26 electrically coupled to the dies 10 with wire-bonds 30. After wire-bonding the dies 10a-b to the leads 26, the microelectronic component assembly 1 is placed in a cavity 92 of a mold apparatus 90 to encapsulate the dies 10a-b and a portion of the lead frame 20. A mold compound 82 is introduced into the cavity 92 and flows around the dies 10a-b to form a casing 80.

One drawback of conventional methods for packaging a leaded device is that the force of the mold compound 82 can move the microelectronic component assembly 1 within the cavity 92 in a direction X generally normal to the dies 10a-b such that the die paddle 22 contacts an internal wall 97 of the mold apparatus 90. As a result, the mold compound 82 cannot flow between die paddle 22 and the internal wall 97, and a surface 24 of the die paddle 22 is an exposed surface that is not encapsulated by the casing 80. Because the die paddle 22 is partially exposed, the packaged device is susceptible to electrical shorting during operation. Conventional processes for insulating the exposed surface 24 include spraying a film over the surface 24 after removing the packaged device from the mold apparatus 90. This approach, however, requires an additional process step and creates a non-planar surface on the backside of the packaged device that is aesthetically displeasing to customers. Accordingly, there is a need to improve conventional processes for packaging multiple dies in a single microelectronic device.

### BRIEF DESCRIPTION OF THE DRAWINGS

FIG. 1 schematically illustrates a microelectronic component assembly including a lead frame and a plurality of dies attached to the lead frame in accordance with the prior art.

FIGS. 2A-2C illustrate stages in one embodiment of a method for manufacturing a microelectronic device.

FIG. 2A is a schematic side cross-sectional view of a portion of a microelectronic component assembly including a lead frame and a plurality of microelectronic dies attached to the lead frame.

FIG. 2B is a schematic side cross-sectional view of a mold apparatus for encapsulating the microelectronic component assembly of FIG. 2A.

FIG. 2C is a schematic side cross-sectional view of the microelectronic device removed from the mold apparatus.

FIGS. 3A and 3B illustrate stages in another embodiment of a method for manufacturing a microelectronic device.

FIG. 3A is a schematic side cross-sectional view of a microelectronic component assembly received in a mold apparatus.

FIG. 3B is a schematic side cross-sectional view of the encapsulated microelectronic assembly after removal from the mold apparatus.

FIGS. 4A and 4B illustrate stages in another embodiment of a method for manufacturing a microelectronic device.

FIG. 4A is a schematic side cross-sectional view of a microelectronic component assembly received in a mold apparatus.

FIG. 4B is a schematic side cross-sectional view of the encapsulated microelectronic device after removal from the mold apparatus.

FIGS. 4C-4E are examples of different configurations of the stand-offs in accordance with several embodiments of the invention.

FIGS. 5A and 5B illustrate stages in another embodiment of a method for manufacturing a microelectronic device.

FIG. 5A is a schematic side cross-sectional view of a microelectronic component assembly received in a mold apparatus.

FIG. 5B is a schematic side cross-sectional view of the encapsulated microelectronic device after removal from the mold apparatus.

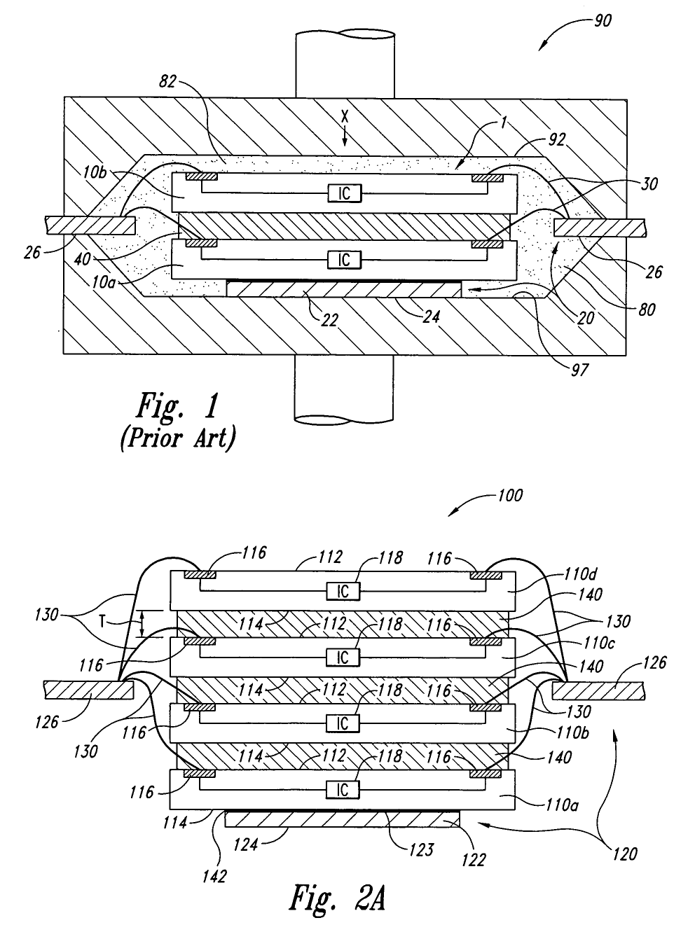

### DETAILED DESCRIPTION

A. Overview

The following disclosure describes several embodiments of microelectronic devices and methods for manufacturing microelectronic devices. An embodiment of one such method includes attaching a first die to a support member, coupling a second die to the first die with the first die positioned between the second die and the support member, and placing the first die, the second die, and the support member in a cavity of a mold with a plurality of stand-offs positioned between an adjacent internal wall of the mold and the support member such that at least a portion of the support member is spaced apart from the internal wall of the mold. The method further includes injecting a mold compound into the mold cavity to encapsulate the first die, the second die, and at least a portion of the support member. The support member can include a die paddle, and the stand-offs may be (a) an integral part of the mold, (b) an integral part of the die paddle, or (c) attached to the die paddle.

In another embodiment, a method includes providing a microelectronic component assembly including (a) a lead frame member with a first surface and a second surface opposite the first surface, (b) a first die attached to the first surface of the lead frame member, and (c) a second die attached to the first die. The method further includes placing the microelectronic component assembly in a cavity of a mold with a generally thermally and/or electrically non-conductive stand-off positioned between the second surface of the lead frame member and an adjacent internal wall of the mold, and flowing a mold compound into the mold cavity to encapsulate at least a portion of the microelectronic component assembly.

Another aspect of the invention is directed to packaged microelectronic devices. In one embodiment, a microelectronic device includes (a) a support member having a first surface and a second surface opposite the first surface, (b) a first die attached to the first surface of the support member, (c) a plurality of first leads electrically coupled to the first die, (d) a second die attached to the first die, (e) a plurality of second leads electrically coupled to the second die, (f) a generally thermally and/or electrically non-conductive stand-off projecting from the second surface of the support member, and (g) a casing covering the first die, the second die, the support member, and at least a portion of the stand-off. The microelectronic device may further include a plurality of first wire-bonds electrically coupling the first die to the first leads, and a plurality of second wire-bonds electrically coupling the second die to the second leads.

In another embodiment, a packaged microelectronic device includes a lead frame member defining a plane, a first die attached to the lead frame member, a plurality of first leads electrically coupled to the first die, a second die attached to the first die such that the first die is positioned between the second die and the lead frame member, a plurality of second leads electrically coupled to the second die, a plurality of stand-offs projecting from the plane, and a casing covering the first die, the second die, and at least a portion of the stand-offs.

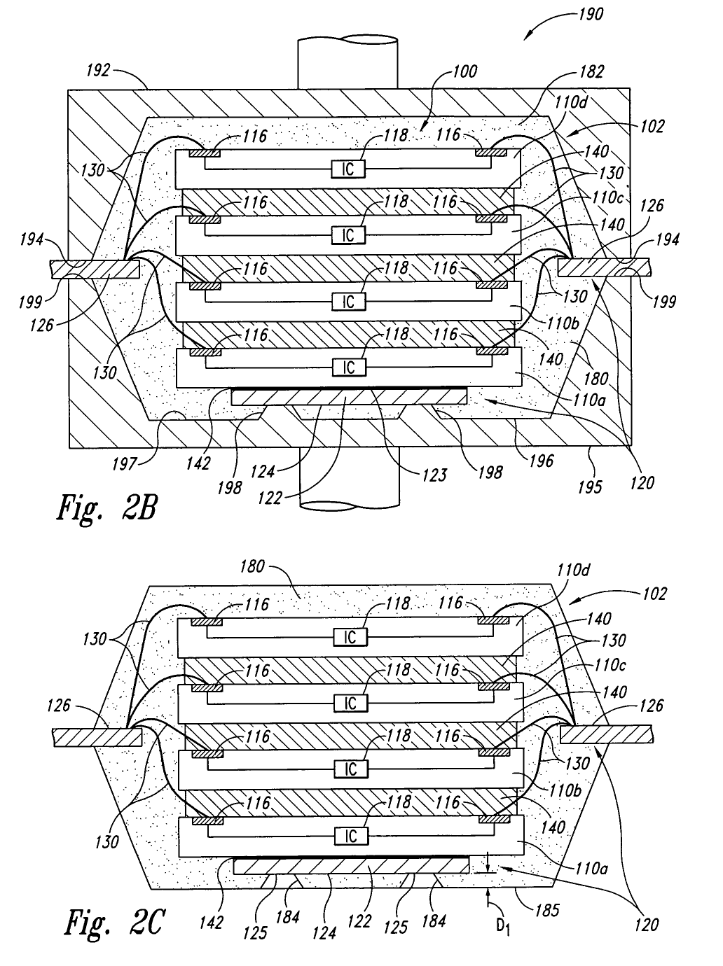

Specific details of several embodiments of the invention are described below with reference to microelectronic devices with four stacked microelectronic dies, but in other embodiments the microelectronic devices can have a different number of stacked dies. Several details describing well-known structures or processes often associated with fabricating microelectronic dies and microelectronic devices are not set forth in the following description for purposes of brevity and clarity. Also, several other embodiments of the invention can have different configurations, components, or procedures than those described in this section. A person of ordinary skill in the art, therefore, will accordingly understand that the invention may have other embodiments with additional elements, or the invention may have other embodiments without several of the elements shown and described below with reference to FIGS. 2A-5B. Where the context permits, singular or plural terms may also include the plural or singular term, respectively. Moreover, unless the word “or” is expressly limited to mean only a single item exclusive from other items in reference to a list of at least two items, then the use of “or” in such a list is to be interpreted as including (a) any single item in the list, (b) all of the items in the list, or (c) any combination of the items in the list. Additionally, the term “comprising” is used throughout to mean including at least the recited feature(s) such that any greater number of the same features and/or types of other features and components are not precluded.

B. Embodiments of Methods for Manufacturing Microelectronic Devices

FIGS. 2A-2C illustrate stages in one embodiment of a method for manufacturing a microelectronic device. For example, FIG. 2A is a schematic side cross-sectional view of a portion of a microelectronic component assembly 100 including a plurality of microelectronic dies 110 (shown individually as 110a-d) and a lead frame 120 carrying the dies 110. The individual dies 110 include an active side 112, a backside 114 opposite the active side 112, a plurality of terminals 116 (e.g., bond-pads) arranged in an array on the active side 112, and an integrated circuit 118 (shown schematically) operably coupled to the terminals 116. Although the illustrated dies 110 have the same structure, in other embodiments the dies 110 may have different features or otherwise perform different functions.

The lead frame 120 includes a die paddle 122 for carrying the microelectronic dies 110 and a plurality of leads 126 (only two are shown) for providing external electrical contacts for the dies 110. The die paddle 122 includes a first surface 123 attached to the backside 114 of a first die 110a with an adhesive 142 and a second surface 124 opposite the first surface 123. In the illustrated embodiment, the die paddle 122 also carries (a) a second die 110b that is attached to the active side 112 of the first die 110a with an adhesive 140, (b) a third die 110c that is attached to the active side 112 of the second die 110b with the adhesive 140, and (c) a fourth die 110d that is attached to the active side 112 of the third die 110c with the adhesive 140. The adhesives 140 can be an epoxy or another suitable material for connecting adjacent dies 110 together. The illustrated adhesives 140 have a thickness T sized to space the adjacent dies 110 apart by a sufficient distance so that a plurality of wire-bonds 130 can pass between the dies 110 and electrically couple the dies 110 to the leads 126. Specifically, each wire-bond 130 electrically connects a terminal 116 to a particular lead 126. Although the illustrated adhesives 140 cover the terminals 116, in other embodiments the adhesives 140 may be positioned on the dies 110 inboard the terminals 116.

FIG. 2B is a schematic side cross-sectional view of a mold apparatus 190 for encapsulating the microelectronic component assembly 100 of FIG. 2A in accordance with one embodiment of the invention. The mold apparatus 190 includes (a) an upper mold portion 192 having an upper mold cavity 193 and an upper clamping surface 194 outboard the cavity 193, and (b) a lower mold portion 195 having a lower mold cavity 196 and a lower clamping surface 199 outboard the cavity 196. The upper and lower mold cavities 193 and 196 are configured to receive the microelectronic dies 110, the die paddle 122, and the inner portion of the leads 126. The upper and lower clamping surfaces 194 and 199 are configured to receive the intermediate portion of the leads 126 so that the outer portion of the leads 126 can be positioned outside the cavities 193 and 196. The illustrated lower mold portion 195 also includes an internal wall 197 adjacent to the second surface 124 of the die paddle 122 and a plurality of stand-offs or projections 198 projecting from the internal wall 197 toward the second surface 124. The projections 198 are sized and arranged to space the die paddle 122 away from the internal wall 197. Although the projections 198 contact the second surface 124 of the die paddle 122, in other embodiments the projections 198 may not contact the second surface 124. In either case, the second surface 124 of the die paddle 122 does not contact the internal wall 197 of the lower mold portion 195.

After placing the microelectronic component assembly 100 within the mold apparatus 190, a mold compound 182 is introduced into the upper and lower mold cavities 193 and 196 and flows around the assembly 100 to form a casing 180. The casing 180 encapsulates the dies 110, the wire-bonds 130, at least a portion of the die paddle 122, and the inner portion of the leads 126. The resulting encapsulated microelectronic component assembly 100 forms a packaged microelectronic device 102.

FIG. 2C is a schematic side cross-sectional view of the microelectronic device 102 removed from the mold apparatus 190. The casing 180 includes a plurality of recesses 184 at the die paddle 122 corresponding to the size and position of the projections 198 (FIG. 2B). In the illustrated casing 180, the recesses 184 extend between an external surface 185 of the casing 180 and the second surface 124 of the die paddle 122 and expose corresponding portions 125 of the second surface 124. In other embodiments, however, the recesses 184 may not expose portions of the second surface 124. In either case, the die paddle 122 is spaced apart from the external surface 185 of the casing 180 by a distance D₁, which corresponds to the height of the projections 198 (FIG. 2B).

One feature of the method of manufacturing the microelectronic device 102 illustrated in FIGS. 2A-2C is that the mold apparatus 190 includes projections 198 for spacing the die paddle 122 away from the adjacent internal wall 197 of the mold apparatus 190 and properly positioning the microelectronic component assembly 100 within the cavities 193 and 196. As a result, the force of the mold compound 182 flowing into the cavities 193 and 196 cannot move the microelectronic component assembly 100 downward such that the die paddle 122 contacts the internal wall 197 of the mold apparatus 190. An advantage of this feature is that the mold compound 182 flows between the internal wall 197 and the second surface 124 of the die paddle 122 and spaces the die paddle 122 apart from the exterior surface 185 of the casing 180, which reduces the likelihood of shorting during operation.

C. Additional Embodiments of Methods for Manufacturing Microelectronic Devices

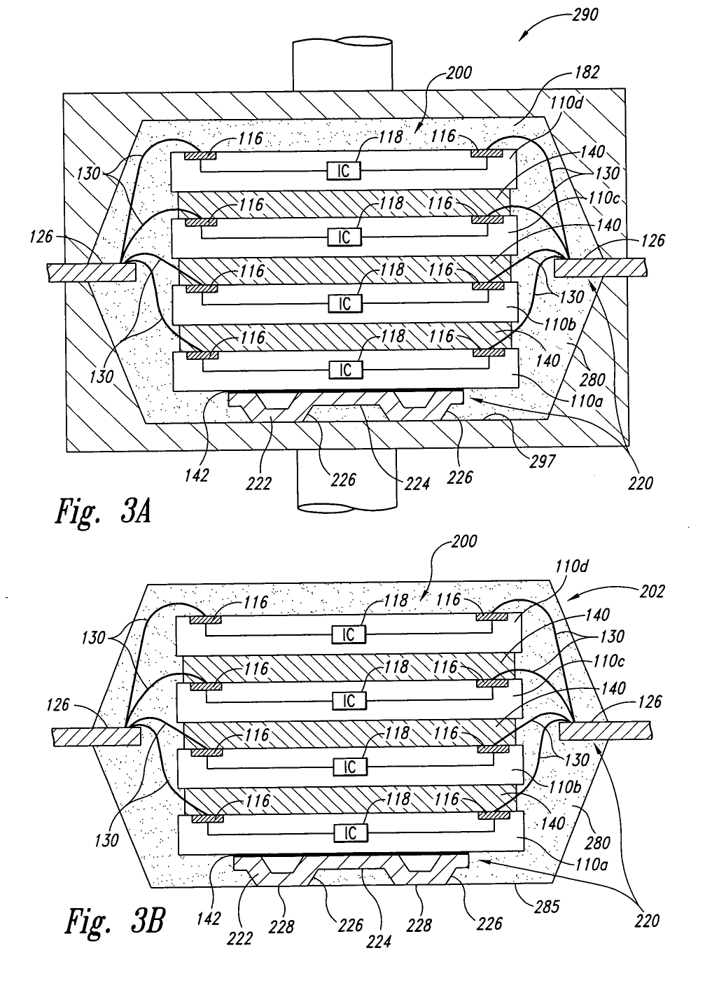

FIGS. 3A and 3B illustrate stages in another embodiment of a method for manufacturing a microelectronic device. For example, FIG. 3A is a schematic side cross-sectional view of a microelectronic component assembly 200 received in a mold apparatus 290. The illustrated microelectronic component assembly 200 is generally similar to the microelectronic component assembly 100 described above with reference to FIGS. 2A-2C. For example, the microelectronic component assembly 200 includes (a) a lead frame 220 with a die paddle 222 and a plurality of leads 126, and (b) a plurality of dies 110 carried by the die paddle 222 and wire-bonded to corresponding leads 126. The illustrated die paddle 222, however, includes a base 224 and a plurality of stand-offs or projections 226 projecting from the base 224. The projections 226 are sized to space the base 224 of the die paddle 222 away from an internal wall 297 of the mold apparatus 290 so that the mold compound 182 can flow between the internal wall 297 and the base 224. Although the illustrated die paddle 222 is bent to form the projections 226, in other embodiments the base and the projections may not be integral members of the same structure, but rather the projections can be attached to the base. Moreover, although in the illustrated embodiment the projections 226 contact the internal wall 297 of the mold apparatus 290, in other embodiments the projections 226 may not contact the wall 297, but rather the projections 226 may be spaced apart from the wall 297. In either case, the mold compound 182 forms a casing 280 that encapsulates the dies 110, the wire-bonds 130, the inner portion of the leads 126, the base 224, and at least a portion of the projections 226.

FIG. 3B is a schematic side cross-sectional view of the encapsulated microelectronic component assembly 200 after removal from the mold apparatus 290. The encapsulated microelectronic component assembly 200 forms a packaged microelectronic device 202 having exposed sections 228 of the lead frame 220. The exposed sections 228 are generally coplanar with an external surface 285 of the casing 280. In other embodiments, however, the projections 226 may not include the exposed sections 228, but rather may be completely encapsulated by the casing 280. An advantage of the encapsulated microelectronic component assembly 200 illustrated in FIGS. 3A and 3B is that the assembly 200 can be manufactured without a specialized mold apparatus, such as the mold apparatus 190 illustrated in FIG. 2B.

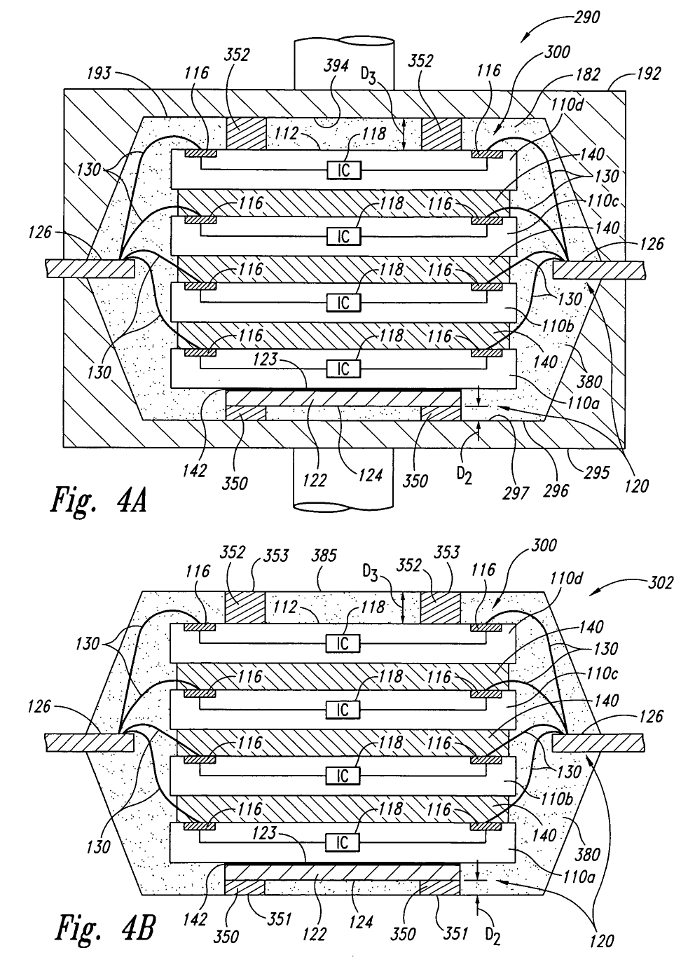

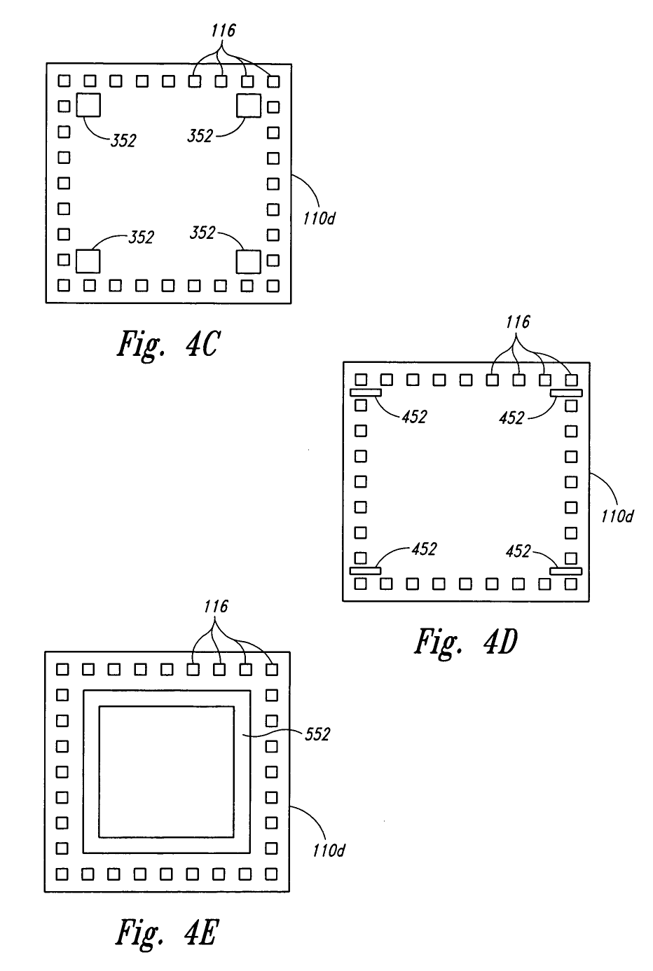

FIGS. 4A and 4B illustrate stages in another embodiment of a method for manufacturing a microelectronic device. FIG. 4A is a schematic side cross-sectional view of a microelectronic component assembly 300 received in a mold apparatus 290. The illustrated microelectronic component assembly 300 is generally similar to the microelectronic component assembly 100 described above with reference to FIGS. 2A-2C. For example, the microelectronic component assembly 300 includes (a) a lead frame 120 with a die paddle 122 and a plurality of leads 126, and (b) a plurality of dies 110 carried by the die paddle 122 and wire-bonded to corresponding leads 126. The illustrated microelectronic component assembly 300 further includes a plurality of first stand-offs 350 (only two of which are shown) attached to the second surface 124 of the die paddle 122 and a plurality of second stand-offs 352 (only two of which are shown) attached to the active side 112 of the fourth die 110d. The first stand-offs 350 are sized to space the second surface 124 of the die paddle 122 away from the internal wall 297 of the lower mold portion 295 by a distance D₂, and the second stand-offs 352 are sized to space the active side 112 of the fourth die 110d away from an internal wall 394 of the upper mold portion 192 by a distance D₃.

The illustrated first and second stand-offs 350 and 352 can be made of a resilient material so that when the assembly 300 is placed in the mold apparatus 290 and the upper and lower mold portions 192 and 295 are closed, the first and second stand-offs 350 and 352 deform to avoid crushing the dies 110. For example, the resilient stand-offs can be formed by attaching a low modulus tape, printing a low modulus adhesive film, dispensing a low modulus epoxy dot, or other suitable processes. In other embodiments, however, the first and second stand-offs 350 and 352 may not be made of a resilient or deformable material. For example, in several embodiments, the microelectronic component assembly 300 may have a height less than the depth of the cavities 193 and 296 such that the first and/or second stand-offs 350 and 352 do not contact the internal walls 297 and 394. In either case, after placing the assembly 300 in the mold apparatus 290, the mold compound 182 is injected into the cavities 193 and 296 and forms a casing 380 that encapsulates the dies 110, the wire-bonds 130, the inner portion of the leads 126, the die paddle 122, at least a portion of the first stand-offs 350, and at least a portion of the second stand-offs 352.

FIG. 4B is a schematic side cross-sectional view of the encapsulated microelectronic component assembly 300 after removal from the mold apparatus 290. The illustrated encapsulated microelectronic component assembly 300 forms a packaged microelectronic device 302 with the first stand-offs 350 having an exposed surface 351 that is generally coplanar with an external surface 385 of the casing 380, and the second stand-offs 352 having an exposed surface 353 that is generally coplanar with the external surface 385 of the casing 380. In several embodiments, the first and second stand-offs 350 and 352 can be made out of a material having an appearance generally similar to that of the casing 380 to improve the aesthetics of the device 302. In other embodiments, however, one or more of the first and/or second stand-offs 350 and/or 352 can be completely encapsulated by the casing 380.

FIGS. 4C-4E are examples of different configurations of the second stand-offs in accordance with several embodiments of the invention. For example, FIG. 4C is a top plan view of the fourth die 110d and the second stand-offs 352 with the wire-bonds 130 removed. The illustrated second stand-offs 352 are positioned inboard the terminals 116 and arranged at the corners of the fourth die 110d. In FIG. 4D, however, a plurality of second stand-offs 452 are arranged such that each stand-off 452 extends between two adjacent terminals 116. FIG. 4E illustrates a single second stand-off 552 that forms a perimeter inboard the terminals 116. In other embodiments, the second stand-offs can have different cross-sectional shapes and/or be arranged in different patterns. For example, the stand-offs can be placed anywhere on the surface of the fourth die 110d provided that the stand-offs do not interfere with the connection between the wire-bonds and the die 110d.

One feature of the microelectronic device 302 illustrated in FIGS. 4A-4B is that the device 302 includes a plurality of first stand-offs 350 positioned between the die paddle 122 and the interior wall 297 of the lower mold portion 295 and a plurality of second stand-offs 352 positioned between the fourth die 110d and the internal wall 394 of the upper mold portion 192. As a result, the first and second stand-offs 350 and 352 space the lead frame 120 and the fourth die 110d apart from the mold apparatus 290 and properly position the assembly 300 within the cavities 193 and 296. An advantage of this feature is that the die paddle 122, the wire-bonds 130, and the fourth die 110d are completely encapsulated, which reduces and/or eliminates the possibility of shorting during operation.

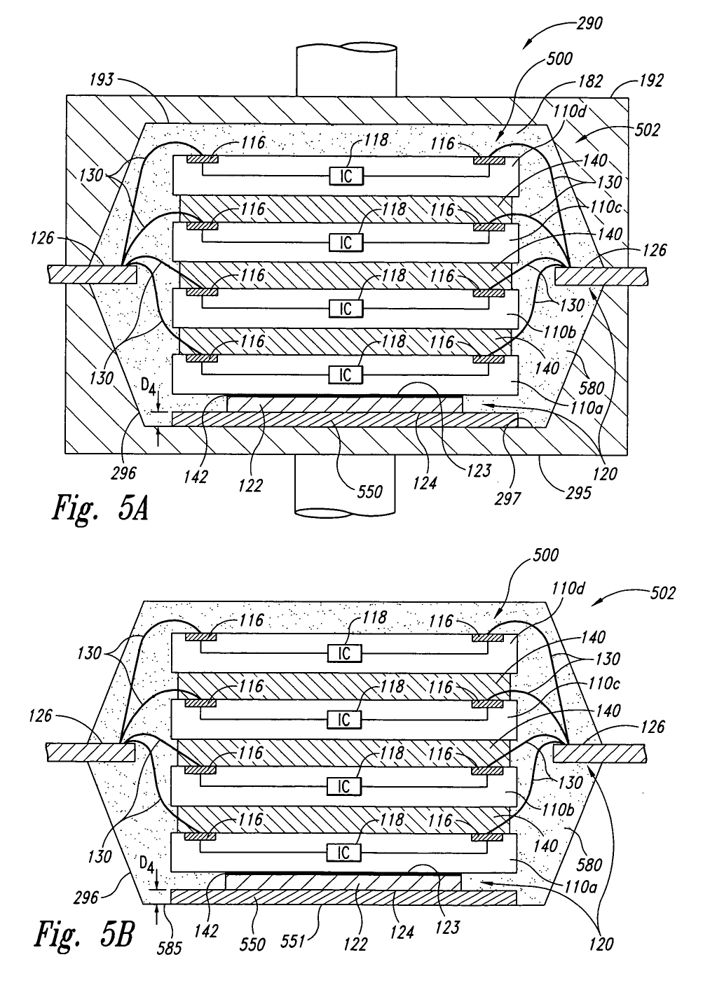

FIGS. 5A and 5B illustrate stages in another embodiment of a method for manufacturing a microelectronic device. For example, FIG. 5A is a schematic side cross-sectional view of a microelectronic component assembly 500 received in a mold apparatus 290. The illustrated microelectronic component assembly 500 is generally similar to the microelectronic component assembly 100 described above with reference to FIGS. 2A-2C. For example, the microelectronic component assembly 500 includes (a) a lead frame 120 with a die paddle 122 and a plurality of leads 126, and (b) a plurality of microelectronic dies 110 carried by the die paddle 122 and wire-bonded to corresponding leads 126. The illustrated microelectronic component assembly 500, however, further includes a stand-off 550 attached to the second surface 124 of the die paddle 122. The stand-off 550 can be a generally thermally and/or electrically non-conductive member sized to space the die paddle 122 apart from the internal wall 297 of the mold apparatus 290 by a desired distance D₄. For example, the stand-off 550 may be a silicon substrate, a polyimide tape, a lead lock tape, a LOC tape, or another suitable material. After placing the microelectronic component assembly 500 in the mold apparatus 290, the mold compound 182 is injected into the cavities 193 and 296 and forms a casing 580 encapsulating the dies 110, the wire-bonds 130, the inner portion of the leads 126, the die paddle 122, and at least a portion of the stand-off 550.

FIG. 5B is a schematic side cross-sectional view of the encapsulated microelectronic component assembly 500 after removal from the mold apparatus 290. The encapsulated microelectronic component assembly 500 forms a packaged microelectronic device 502 with the stand-off 550 having an external surface 551 that is exposed and generally coplanar with an external surface 585 of the casing 580. In other embodiments, however, the surface 551 may be covered by the casing 580 and spaced apart from the external surface 585 of the casing 580.

From the foregoing, it will be appreciated that specific embodiments of the invention have been described herein for purposes of illustration, but that various modifications may be made without deviating from the spirit and scope of the invention. For example, many of the elements of one embodiment can be combined with other embodiments in addition to or in lieu of the elements of the other embodiments. Accordingly, the invention is not limited except as by the appended claims.

I/We claim:

1. A method for manufacturing a microelectronic device, the method comprising:
attaching a first die to a support member;
coupling a second die to the first die with the first die positioned between the second die and the support member;
placing the first die, the second die, and the support member in a cavity of a mold with a plurality of stand-offs positioned between an adjacent internal wall of the mold and the support member such that at least a portion of the support member is spaced apart from the internal wall of the mold; and
injecting a mold compound into the mold cavity to encapsulate the first die, the second die, and at least a portion of the support member.

2. The method of claim 1 wherein:
the support member comprises a lead frame member;
the stand-offs comprise a plurality of projections projecting from the internal wall of the mold; and
placing the first die, the second die, and the support member in the cavity comprises disposing the lead frame member in the cavity with the projections positioned between the lead frame member and the internal wall.

3. The method of claim 1 wherein injecting the mold compound into the cavity comprises forming a casing with a plurality of apertures exposing sections of the support member inboard the first die.

4. The method of claim 1 wherein the support member comprises a die paddle, and wherein attaching the first die to the support member comprises coupling the first die to the die paddle.

5. The method of claim 1 wherein:
the support member comprises a lead frame member with a base and a plurality of projections inboard the first die projecting from the base;
the stand-offs comprise the projections of the lead frame member; and
placing the first die, the second die, and the support member in the cavity comprises positioning the projections between the internal wall of the mold and the base.

6. The method of claim 1 wherein:
the support member comprises a lead frame member;
the stand-offs comprise a plurality of discrete resilient members attached to the lead frame member; and
placing the first die, the second die, and the support member in the cavity comprises positioning the resilient members between the internal wall of the mold and the lead frame member.

7. The method of claim 1 wherein:
the support member comprises a lead frame member;
the stand-offs comprise a first resilient member attached to the lead frame member;
the method further comprises attaching a second resilient member to the second die with the second die positioned between the second resilient member and the first die; and
placing the first die, the second die, and the support member in the cavity comprises positioning the first resilient member between the adjacent internal wall and the lead frame member and positioning the second resilient member between the second die and an adjacent internal wall of the mold.

8. The method of claim 1 wherein:
the support member comprises a lead frame member;
the stand-offs comprise a generally thermally non-conductive member attached to the lead frame member; and
placing the first die, the second die, and the support member in the cavity comprises positioning the generally thermally non-conductive member between the lead frame member and the internal wall of the mold.

9. The method of claim 1 wherein:
the support member comprises a lead frame member;
the stand-offs comprise a generally thermally non-conductive member attached to the lead frame member;
placing the first die, the second die, and the support member in the cavity comprises contacting the internal wall of the mold with the generally thermally non-conductive member; and
injecting the mold compound into the mold cavity comprises encapsulating a portion of the generally thermally non-conductive member without covering an exposed section of the generally thermally non-conductive member.

10. The method of claim 1, further comprising:
wire-bonding the first die to a plurality of first leads; and
wire-bonding the second die to a plurality of second leads.

11. The method of claim 1, further comprising attaching the stand-offs to the support member.

12. A method for manufacturing a microelectronic device, the method comprising:
providing a microelectronic component assembly including (a) a lead frame member with a first surface and a second surface opposite the first surface, (b) a first die attached to the first surface of the lead frame member, and (c) a second die attached to the first die;
placing the microelectronic component assembly in a cavity of a mold with a generally thermally non-conductive stand-off positioned between the second surface of the lead frame member and an adjacent internal wall of the mold; and
flowing a mold compound into the mold cavity to encapsulate at least a portion of the microelectronic component assembly.

13. The method of claim 12 wherein:
the stand-off comprises a projection projecting from the internal wall of the mold; and
placing the microelectronic component assembly in the cavity comprises positioning the lead frame member in the cavity with the projection at least proximate to a portion of the lead frame member inboard the first die.

14. The method of claim 12 wherein flowing the mold compound into the cavity comprises forming a casing with an aperture exposing a section of the lead frame member.

15. The method of claim 12 wherein:
the stand-off comprises a resilient member attached to the lead frame member; and
placing the microelectronic component assembly in the cavity comprises positioning the resilient member between the internal wall of the mold and the lead frame member.

16. The method of claim 12 wherein:
the stand-off comprises a first resilient member attached to the lead frame member;
the method further comprises attaching a second resilient member to the second die with the second die positioned between the second resilient member and the first die; and
placing the microelectronic component assembly in the cavity comprises positioning the first resilient member between the adjacent internal wall and the lead frame member and positioning the second resilient member between the second die and an adjacent internal wall of the mold.

17. The method of claim 12 wherein:
the stand-off comprises a first stand-off; and
placing the microelectronic component assembly in the cavity comprises positioning the microelectronic component assembly in the cavity with the first stand-off and a second stand-off disposed between the second surface of the lead frame member and the adjacent internal wall of the mold.

18. The method of claim 12 wherein flowing the mold compound into the mold cavity comprises encapsulating a portion of the generally thermally non-conductive stand-off without covering an exposed section of the generally thermally non-conductive stand-off.

19. A method for manufacturing a microelectronic device, the method comprising:
providing a microelectronic component assembly including (a) a lead frame member with a first surface and a second surface opposite the first surface, (b) a first die attached to the first surface of the lead frame member, and (c) a second die attached to the first die;
a step for positioning the microelectronic component assembly in a cavity of a mold with the second surface of the lead frame member spaced apart from an internal wall of the mold; and
injecting a mold compound into the mold cavity to encapsulate at least a portion of the microelectronic component assembly.

20. The method of claim 19 wherein:
the mold comprises a plurality of projections projecting from the internal wall; and
the step for positioning the microelectronic component assembly comprises placing the component assembly in the cavity with the projections at least proximate to a portion of the lead frame member inboard the first die.

21. The method of claim 19 wherein injecting the mold compound into the mold cavity comprises forming a casing with a plurality of apertures exposing sections of the lead frame member inboard the first die.

22. The method of claim 19 wherein:
the lead frame member comprises a base and a plurality of projections inboard the first die projecting from the base; and
the step for positioning the microelectronic component assembly comprises placing the lead frame member in the cavity with the projections positioned between the internal wall of the mold and the base of the lead frame member.

23. The method of claim 19 wherein the step for positioning the microelectronic component assembly comprises placing the component assembly in the cavity with a resilient member positioned between the lead frame member and the internal wall of the mold.

24. The method of claim 19 wherein:
the step for positioning the microelectronic component assembly comprises placing the component assembly in the cavity with a resilient member positioned between the lead frame member and the internal wall of the mold; and
the method further comprises (a) attaching a second resilient member to the second die with the second die positioned between the second resilient member and the first die, and (b) a step for positioning the microelectronic component assembly in the cavity with the second die spaced apart from an adjacent internal surface of the mold.

25. The method of claim 19 wherein the step for positioning the microelectronic component assembly comprises placing the component assembly in the cavity with a generally thermally non-conductive member positioned between the lead frame member and the internal surface of the mold.

26. A packaged microelectronic device, comprising:
a support member having a first surface and a second surface opposite the first surface;
a first die attached to the first surface of the support member;
a plurality of first leads electrically coupled to the first die;
a second die attached to the first die;
a plurality of second leads electrically coupled to the second die;
a generally thermally non-conductive stand-off projecting from the second surface of the support member; and
a casing covering the first die, the second die, the support member, and at least a portion of the stand-off, the first leads, and the second leads.

27. The packaged microelectronic device of claim 26 wherein the support member comprises a die paddle.

28. The packaged microelectronic device of claim 26 wherein the generally thermally non-conductive stand-off comprises a first stand-off, and wherein the microelectronic device further comprises a plurality of second stand-offs projecting from the support member.

29. The packaged microelectronic device of claim 26 wherein the generally thermally non-conductive stand-off comprises a resilient member attached to the second surface of the support member.

30. The packaged microelectronic device of claim 26 wherein the generally thermally non-conductive stand-off includes an exposed surface.

31. The packaged microelectronic device of claim 26 wherein the generally thermally non-conductive stand-off comprises a first stand-off, and wherein the packaged microelectronic device further comprises a second stand-off attached to the second die such that the second die is positioned between the second stand-off and the first die.

32. The packaged microelectronic device of claim 26 wherein the generally thermally non-conductive stand-off comprises a first resilient member, and wherein the packaged microelectronic device further comprises a second resilient member attached to the second die such that the second die is positioned between the second resilient member and the first die.

33. The packaged microelectronic device of claim 26, further comprising a plurality of first wire-bonds electrically coupling the first die to the first leads, and a plurality of second wire-bonds electrically coupling the second die to the second leads.

34. A packaged microelectronic device, comprising:
a lead frame member defining a plane;
a first die attached to the lead frame member;
a plurality of first leads electrically coupled to the first die;
a second die attached to the first die such that the first die is positioned between the second die and the lead frame member;
a plurality of second leads electrically coupled to the second die;
a plurality of stand-offs projecting from the plane; and
a casing covering the first die, the second die, and at least a portion of the lead frame member, the first lead, the second lead, and the stand-offs.

35. The packaged microelectronic device of claim 34 wherein the lead frame member comprises a base defining the plane and a plurality of projections projecting from the base, and wherein the stand-offs comprise the projections.

36. The packaged microelectronic device of claim 34 wherein the stand-offs comprise a plurality of resilient members attached to the lead frame member.

37. The packaged microelectronic device of claim 34 wherein the individual stand-offs comprise a generally thermally non-conductive member.

38. The packaged microelectronic device of claim 34 wherein the individual stand-offs comprise an exposed surface.

39. The packaged microelectronic device of claim 34 wherein the lead frame member comprises a die paddle.

40. The packaged microelectronic device of claim 34 wherein the stand-offs comprise a plurality of first stand-offs, and wherein the microelectronic device further comprises a plurality of second stand-offs attached to the second die such that the second die is positioned between the second stand-offs and the first die.

41. A packaged microelectronic device, comprising:
a lead frame member;
a first die attached to the lead frame member;
a plurality of first leads electrically coupled to the first die;
a second die attached to the first die such that the first die is positioned between the second die and the lead frame member;
a plurality of second leads electrically coupled to the second die; and
a casing covering the first die, the second die, and a portion of the lead frame member, wherein the casing includes a plurality of apertures exposing selected sections of the lead frame member.

42. The packaged microelectronic device of claim 41 wherein the lead frame member comprises a die paddle.

43. The packaged microelectronic device of claim 41 wherein the apertures comprise molded holes in the casing.

44. The packaged microelectronic device of claim 41 wherein the casing includes an external surface adjacent to the lead frame member, and wherein the lead frame member is spaced apart from the external surface.

45. A packaged microelectronic device, comprising:
a lead frame member having a first surface and a second surface opposite the first surface;
a first die attached to the first surface of the lead frame member;
a plurality of first leads wire-bonded to the first die;
a second die attached to the first die;
a plurality of second leads wire-bonded to the second die;
a casing covering the first die, the second die, and at least a portion of the lead frame member; and
means for spacing the lead frame member apart from an adjacent exterior surface of the casing.

46. The packaged microelectronic device of claim 45 wherein the means for spacing the lead frame member comprise a generally thermally non-conductive stand-off attached to the second surface of the lead frame member.

47. The packaged microelectronic device of claim 45 wherein the means for spacing the lead frame member comprise a plurality of stand-offs.

48. The packaged microelectronic device of claim 45 wherein:
the lead frame member comprises a base and a plurality of projections projecting from the base; and
the means for spacing the lead frame member comprise the plurality of projections.

49. The packaged microelectronic device of claim 45 wherein the means for spacing the lead frame member comprise a resilient member attached to the second surface of the lead frame member.

50. The packaged microelectronic device of claim 45 wherein the means for spacing the lead frame member comprise an exposed surface.

51. The packaged microelectronic device of claim 45, further comprising a stand-off attached to the second die such that the second die is positioned between the stand-off and the first die.
